(19) United States
(12) Patent Application Publication
(10) Pub. No.: US 2025/0137123 A1
(43) Pub. Date: May 1, 2025

(54) MULTI-COMPONENT THIN FILM, METHOD OF MANUFACTURING THE SAME, AND IC DEVICE INCLUDING THE MULTI-COMPONENT THIN FILM

(71) Applicant: Samsung Electronics Co., Ltd., Suwon-si (KR)

(72) Inventors: Jungmin PARK, Suwon-si (KR); Haeryong KIM, Suwon-si (KR); Boeun PARK, Suwon-si (KR); Jeongil BANG, Suwon-si (KR); Jooho LEE, Suwon-si (KR); Hanjin LIM, Suwon-si (KR); Hyungsuk JUNG, Suwon-si (KR); Sumin HWANG, Suwon-si (KR)

(73) Assignee: Samsung Electronics Co., Ltd., Suwon-si (KR)

(21) Appl. No.: 18/830,845

(22) Filed: Sep. 11, 2024

(30) Foreign Application Priority Data
Nov. 1, 2023 (KR) 10-2023-0149281

(51) Int. Cl. C23C 16/455; C23C 16/40; C23C 16/44; H01L 27/06; H10B 12/00

(52) U.S. Cl. CPC C23C 16/45531; C23C 16/409; C23C 16/4408; C23C 16/45553; H10D 1/684; H10D 84/811; H10B 12/315; H10D 1/714; H10D 1/716

(57) ABSTRACT

A method of manufacturing a multi-component thin film includes providing a substrate into a process chamber, performing a first cycle, the first cycle including forming a first atomic layer including a first precursor on the substrate by using an atomic layer deposition process, performing a third cycle, the third cycle including injecting an additive onto the first atomic layer, and performing a second cycle, the second cycle including forming a second atomic layer including a second precursor on the first atomic layer and the additive by using an atomic layer deposition process, wherein a thermal decomposition temperature of the additive is lower than each of a thermal decomposition temperature of the first precursor and a thermal decomposition temperature of the second precursor.

### CROSS-REFERENCE TO RELATED APPLICATION

This application is based on and claims priority under 35 U.S.C. § 119 to Korean Patent Application No. 10-2023-0149281, filed on Nov. 1, 2023, in the Korean Intellectual Property Office, the disclosure of which is incorporated by reference herein in its entirety.

### BACKGROUND

The inventive concepts relate to a multi-component thin film, a method of manufacturing the same, and an integrated circuit (IC) device including a multi-component thin film.

In a semiconductor manufacturing process, a thin film deposition process may refer to a process of forming a conductive material, an insulating material, and a semiconductor material on a wafer. A thin film deposition method may include an atomic layer deposition (ALD) process and a chemical vapor deposition (CVD) process. The ALD process may be a process of depositing one atomic layer in one time and be used when a miniaturization process is required.

### SUMMARY

The inventive concepts provide a method of manufacturing a multi-component thin film, which includes injecting an additive with a low thermal decomposition temperature.

The technical objectives of the inventive concepts are not limited to the above disclosure; other objectives may become apparent to those of ordinary skill in the art based on the following descriptions.

According to an aspect of the inventive concepts, there is provided a method of manufacturing a multi-component thin film. The method includes providing a substrate into a process chamber, performing a first cycle, the first cycle comprising forming a first atomic layer on the substrate using an atomic layer deposition process to deposit a first precursor; performing a third cycle, the third cycle including injecting an additive onto the first atomic layer; and performing a second cycle, the second cycle comprising forming a second atomic layer on the first atomic layer and the additive using an atomic layer deposition process to deposit a second precursor, wherein a thermal decomposition temperature of the additive is lower than a thermal decomposition temperature of the first precursor and lower than a thermal decomposition temperature of the second precursor.

According to another aspect of the inventive concepts, there is provided a multi-component thin film including a plurality of atomic layers including a least a first atomic layer and a second atomic layer with different precursors from each other and an additive between two adjacent ones of the plurality of atomic layers, wherein the additive comprises a material with a thermal decomposition temperature lower than thermal decomposition temperatures of both the different precursors.

According to another aspect of the inventive concepts, there is provided an integrated circuit (IC) device including a transistor on a substrate, and a capacitor structure electrically connected to the transistor, wherein the capacitor structure includes a first electrode, a second electrode on the dielectric layer, and a dielectric layer between the first and second electrodes, wherein the dielectric layer includes a plurality of atomic layers including at least a first atomic layer and a second atomic layer with different precursors from each other and an additive between two adjacent ones of the plurality of atomic layers, wherein the additive comprises a material with a thermal decomposition temperature lower than thermal decomposition temperatures of both the different precursors.

### BRIEF DESCRIPTION OF THE DRAWINGS

Embodiments will be more clearly understood from the following detailed description taken in conjunction with the accompanying drawings in which:

FIG. 1A is a flowchart of a method of manufacturing a multi-component thin film, according to at least one embodiment;

FIG. 1B is a diagram a recipe for a method of manufacturing a multi-component thin film, according to at least one embodiment;

FIG. 1C is a diagram of a multi-component thin film according to at least one embodiment;

FIG. 2 is a graph for selecting an additive of a multi-component thin film according to at least one embodiment;

FIG. 3 is a graph showing effects of a multi-component thin film according to at least one embodiment;

FIG. 4 is a cross-sectional view of an integrated circuit (IC) device according to at least one embodiment;

FIG. 5 is an enlarged view of portion CX1 of FIG. 4;

FIGS. 6 and 7 are each a diagram of a recipe for a method of manufacturing a multi-component thin film, according to at least one embodiment;

FIG. 8 illustrates the layout of an IC device according to at least one embodiment;

FIG. 9 is a cross-sectional view taken along line B1-B1′ of FIG. 8;

FIG. 10 is an enlarged view of portion “CX2” of FIG. 9;

FIG. 11 illustrates the layout of an IC device according to at least one embodiment;

FIG. 12 is a cross-sectional view taken along line B2-B2′ of FIG. 11;

FIG. 13 is an enlarged view of portion “CX3” of FIG. 12;

FIG. 14 is an enlarged view of portion “CX4” of FIG. 12; and

FIG. 15 is a view showing the configuration of a system including an IC device, according to at least one embodiment.

### DETAILED DESCRIPTION OF THE EMBODIMENTS

Hereinafter, embodiments will be described in detail with reference to the accompanying drawings. The same reference numerals are used to denote the same elements in the drawings, and repeated descriptions thereof are omitted.

When the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

Although the terms “first,” “second,” “third,” etc., may be used herein to describe various elements, components, regions, layers, and/or sections, these elements, components, regions, layers, and/or sections, should not be limited by these terms. These terms are only used to distinguish one element, component, region, layer, or section, from another region, layer, or section. Thus, a first element, component, region, layer, or section, discussed below may be termed a second element, component, region, layer, or section, without departing from the scope of this disclosure.

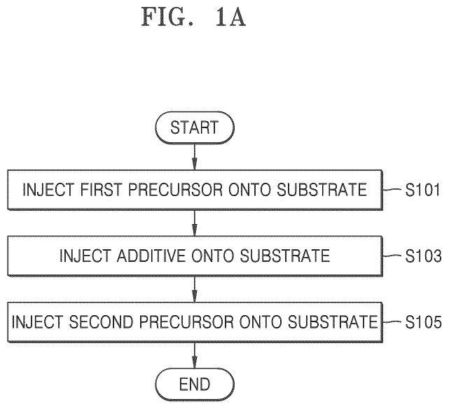

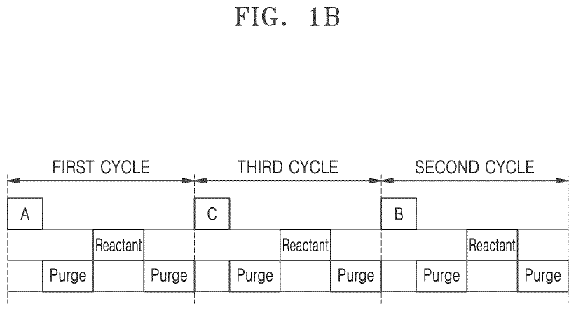

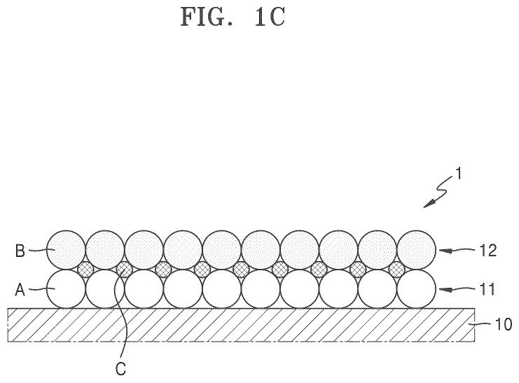

FIG. 1A is a flowchart of a method of manufacturing a multi-component thin film, according to at least one embodiment.

FIG. 1B is a diagram of a recipe for a method of manufacturing a multi-component thin film according to at least one embodiment.

FIG. 1C is a diagram of a multi-component thin film according to at least one embodiment.

Referring to FIGS. 1A to 1C, a multi-component thin film 1 according to at least one embodiment may be manufactured by using an atomic layer deposition (ALD) process. Hereinafter, the multi-component thin film 1 may include a high-k dielectric film, such as a perovskite material film. For example, the multi-component thin film 1 may include at least one of SrTiO₃, HfZrO₂, PbTiO₃, AgNbO₃, Ta₂O₃, BaTiO₃, BiFeO₃, or a combination thereof, without being limited thereto. For example, the multi-component thin film 1 may include an oxide semiconductor, such as indium gallium zinc oxide (IGZO). Hereinafter, for brevity, the description of the multi-component thin film 1 is assumed to be a multi-component thin film 1 including SrTiO₃. Also, for brevity, the multi-component thin film 1 is assumed to include two precursors. However, the inventive concepts are not limited thereto, and the multi-component thin film 1 according to the inventive concepts may include a plurality of atomic layers including at least three precursors.

In some embodiments, the multi-component thin film 1 may include a plurality of atomic layers including respectively different precursors and an additive C between the plurality of atomic layers. For example, the multi-component thin film 1 may include a first atomic layer 11 including a first precursor A and a second atomic layer 12 including a second precursor B.

The multi-component thin film 1 is illustrated as including one first atomic layer 11 and one second atomic layer 12 in FIG. 1C, but the inventive concepts are not limited thereto. A plurality of first atomic layers 11 and a plurality of second atomic layers 12 may be alternately stacked to form the multi-component thin film 1. For example, the multi-component thin film 1 may include a plurality of first atomic layers 11 and a plurality of second atomic layers 12, which are alternately stacked in a vertical direction. In these cases, the additive C may be between the plurality of first atomic layers 11 and the plurality of second atomic layers 12. In these cases, the additive C may be at a content ratio of 10% or less based on a total content of the multi-component thin film 1.

In some embodiments, the additive C may include a material of which a thermal decomposition temperature is lower than thermal decomposition temperatures of the first precursor A and the second precursor B. For example, when each of the first precursor A and the second precursor B includes a material with a thermal decomposition temperature of 200° C., the additive C may include a material with thermal decomposition temperature below 200° C.

In these cases, the first precursor A and the second precursor B may include, for example, a material including a cyclopentadienyl ligand, without being limited thereto. The additive C may include a material including an amine ligand, without being limited thereto. In some embodiments, the first precursor A, the second precursor B, and the additive C may include different metal elements from each other, without being limited thereto. In some embodiments, the first precursor A, the second precursor B, and the additive C may include different ligands. Thus, when the thermal decomposition temperature of the additive C is lower than the thermal decomposition temperatures of the first precursor A and the second precursor B, the first precursor A, the second precursor B, and the additive C may include the same metal element as each other.

The multi-component thin film 1 according to the inventive concepts may include the additive C having a low thermal decomposition temperature, and thus, crystallization of the multi-component thin film 1 may be improved. Also, characteristics of the multi-component thin film 1 may improve. The characteristics of the multi-component thin film 1 according to the inventive concepts are described in detail below along with a method of manufacturing the multi-component thin film 1.

The method of manufacturing the multi-component thin film 1 may include supplying the first precursor A into a process chamber including a substrate 10 (S101). The first precursor A may be adsorbed on the substrate 10. In at least one embodiment, the first precursor A may include a titanium (Ti) precursor, without being limited thereto.

Subsequently, a reactant may be supplied into the process chamber and react with the first precursor A to form a first atomic layer 11. The reactant may be an oxidant, such as ozone (O₃), O₂ plasma, and/or the like. The first precursor A may react with the reactant, and thus, the first atomic layer 11 may be formed on the substrate 10. The first atomic layer 11 may include, for example, titanium oxide (TiO), without being limited thereto.

As used herein, the process of forming the first atomic layer 11 by supplying the first the first precursor A and the reactant to the substrate 10 may be defined as a first cycle. The first cycle may further include removing a residual gas from the process chamber by supplying a purge gas to the process chamber before and/or after the operations of supplying the first precursor A and the reactant to the substrate 10. The purge gas may include a non-reactive gas with respect to the first precursor A and/or the first atomic layer 11, for example, nitrogen (N₂) gas, helium (He) gas, argon (Ar) gas, and/or the like, but without being limited to these examples.

The method of manufacturing the multi-component thin film 1 may include supplying an additive C into the process chamber (S103). In these cases, the additive C may include a zirconium (Zr) precursor, a hafnium (Hf) precursor, and/or a lanthanum (La) precursor, without being limited thereto.

Subsequently, a reactant may be supplied into the process chamber and react with the additive C. The reactant may be an oxidant, such as ozone (O₃), O₂ plasma, and/or the like. The additive C may react with the reactant and be adsorbed on the first atomic layer 11.

As used herein, the process of supplying the additive C and the reactant to the substrate 10 may be defined as a third cycle. The third cycle may further include removing a residual gas from the process chamber by supplying a purge gas to the process chamber before and after the operations of supplying the additive C and the reactant to the substrate 10. The purge gas may include a non-reactive gas with respect to the additive C, for example, N₂ gas, He gas, Ar gas, and/or the like, but without being limited to these examples.

The method of manufacturing the multi-component thin film 1 may include supplying the second precursor B into the process chamber (S105). The second precursor B may be adsorbed on the layer formed using the first precursor A and the additive C. In these cases, the second precursor B may include a strontium (Sr) precursor, without being limited thereto.

Subsequently, a reactant may be supplied into the process chamber and react with the second precursor B to form a second atomic layer 12. The reactant may be an oxidant, such as ozone (O₃), O₂ plasma, and/or the like. The second precursor B may react with the reactant, and thus, the second atomic layer 12 may be deposited on the first atomic layer 11 and the additive C. The second atomic layer 12 may include, for example, strontium oxide (SrO), without being limited thereto.

As used herein, the process of forming the second atomic layer 12 by supplying the second precursor B and the reactant to the substrate 10 may be defined as a second cycle. The second cycle may further include removing a residual gas from the process chamber by supplying a purge gas before and after the operations of supplying the second precursor B and the reactant into the process chamber. The purge gas may be a non-reactive gas with respect to the second precursor B and/or the second atomic layer 12, for example, N₂ gas, He gas, Ar gas, and/or the like, but without being limited thereto.

Thereafter, the first atomic layer 11 and the second atomic layer 12 may be crystallized by using an annealing process to form the multi-component thin film 1. The multi-component thin film 1 is illustrated as including one first atomic layer 11 and one second atomic layer 12 in FIG. 1C, but the inventive concepts is not limited thereto′. By repeating the first to third cycles, a plurality of first atomic layers 11 and a plurality of second atomic layers 12 may be alternately stacked to form the multi-component thin film 1. For example, the multi-component thin film 1 may include a plurality of first atomic layers 11 and a plurality of second atomic layers 12, which are alternately stacked in a vertical direction.

In the method of manufacturing the multi-component thin film 1, the first cycle, the second cycle, and the third cycle may be performed at the same process temperature. Here, the process temperature may refer to an internal temperature of the process chamber during a process of depositing the multi-component thin film 1. For example, the process temperature may be in a range of about 100° C. to about 400° C.

In the method of manufacturing the multi-component thin film 1, according to the inventive concepts, the thermal decomposition temperature of the additive C may be lower than the thermal decomposition temperature of each of the first precursor A and the second precursor B. For example, when the thermal decomposition temperature of each of the first precursor A and the second precursor B is in a range of about 200° C. to about 400° C., the thermal decomposition temperature of the additive C may be in a range of about 100° C. to about 300° C.

In some embodiments, a process temperature of the method of manufacturing the multi-component thin film 1 is set to be lower than the thermal decomposition temperature of the first precursor A and the thermal decomposition temperature of the second precursor B. Also, the process temperature may be higher than the thermal decomposition temperature of the additive C. That is, the additive C may be thermally decomposed during the third cycle. By adding the process of injecting the additive C that is thermally decomposed (e.g., during the third cycle) between the first cycle and the second cycle, the multi-component thin film 1 may be easily formed. By thermally decomposing the additive C on the first atomic layer 11, deposition of the second atomic layer 12 may be facilitated. Also, crystallization of the multi-component thin film 1 may improve.

In a comparative case in which a multi-component thin film is formed using various types of precursors, the respective precursors may have different growth per cycles (GPCs) from each other due to differences in characteristics, such as a reaction temperature of each precursor. When the respective precursors have different GPCs from each other, materials of the precursors have different growth rates from each other, and thus, adjusting a composition ratio of the multi-component thin film may be difficult. As a result, the multi-component thin film may deteriorate.

In the method of manufacturing the multi-component thin film 1, according to the inventive concepts, the additive C may be injected (the third cycle) between a process of depositing the first precursor A (the first cycle) and a process of depositing the second precursor B (the second cycle), and thus, crystallization of the multi-component thin film 1 may improve. The additive C having a lower thermal decomposition temperature than the first precursor A and the second precursor B may be thermally decomposed during the third cycle. The additive C, which is thermally decomposed, may be between the first atomic layer 11 and the second atomic layer 12 and improve the crystallization of the multi-component thin film 1.

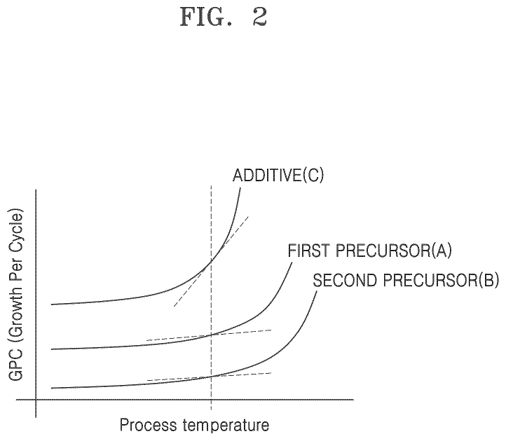

FIG. 2 is a graph for selecting an additive of a multi-component thin film according to at least one embodiment.

Referring to FIG. 2, in a method of manufacturing a multi-component thin film 1, according to at least one embodiment, an additive having a higher GPC than a first precursor A and having a higher GPC than a second precursor B may be selected as the additive C. The additive C having a relatively high GPC may be injected between the first precursor A and the second precursor B, each of which has a relatively low GPC.

A thermal decomposition temperature of the additive C may be lower than a thermal decomposition temperature of the first precursor A and a thermal decomposition temperature of the second precursor B. Accordingly, the additive C may be thermally decomposed at the same process temperature. That is, at a process temperature of the method of manufacturing the multi-component thin film 1, a GPC of the additive C may be higher than a GPC of the first precursor A and a GPC of the second precursor B.

The additive C having a high GPC may be injected (a third cycle) between a process of depositing the first precursor A (a first cycle) and a process of depositing the second precursor B (a second cycle), and thus, crystallization of the multi-component thin film 1 may improve. By injecting the additive C having a high GPC, a bandgap of the multi-component thin film 1 may be reduced, and thus, the crystallization of the multi-component thin film 1 may improve.

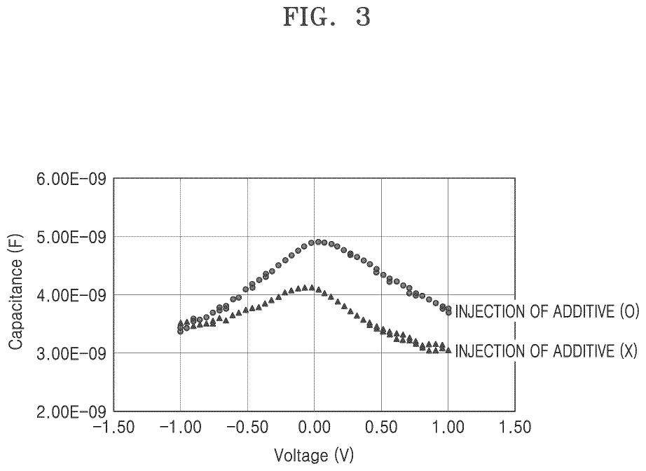

FIG. 3 is a graph showing effects of a multi-component thin film 1 according to at least one embodiment.

Referring to FIG. 3, characteristics of the multi-component thin film 1 according to the inventive concepts may be improved by injecting an additive C to the substrate 10. It can be seen that a capacitance of the multi-component thin film 1 in which the additive C is injected (“O”) may increase as compared to a case in which the additive C is not injected (“X”). In some embodiments, from the graph of FIG. 3, it can be seen that the multi-component thin film 1 in which the additive C is injected includes characteristics of a paraelectric material layer.

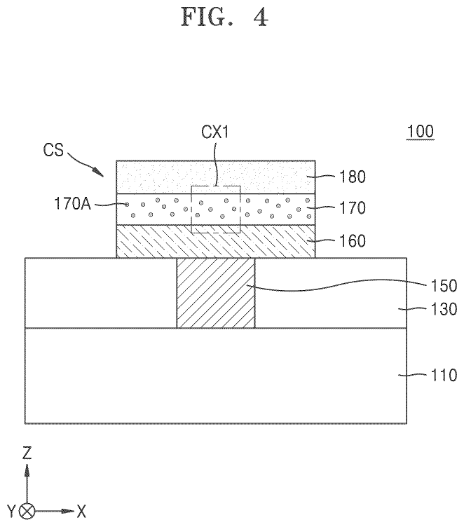

FIG. 4 is a cross-sectional view of an integrated circuit (IC) 100 device according to at least one embodiment.

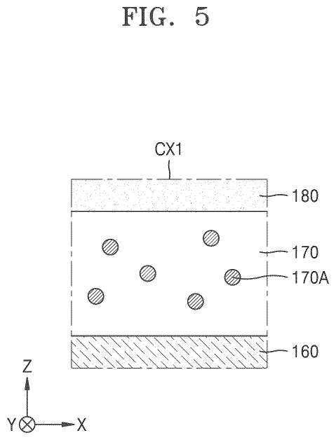

FIG. 5 is an enlarged view of portion CX1 of FIG. 4.

Referring to FIGS. 4 and 5 together, the IC device 100 according to the inventive concepts may include a lower insulating layer 130 on a substrate 110, a contact 150 covered by the lower insulating layer 130 on the substrate 110, and a capacitor structure CS on the contact 150.

The substrate 110 may include an elemental semiconductor material, such as silicon (Si) and germanium (Ge), and/or a compound semiconductor material, such as silicon germanium (SiGe), silicon carbide (SiC), gallium arsenide (GaAs), indium arsenide (InAs), or indium phosphide (InP). In some embodiments, the substrate 110 may include a conductive region, for example, a doped well or a doped structure.

Although not shown, a switching device (e.g., a transistor and/or a diode) configured to provide signals to the capacitor structure CS may be in and/or on the substrate 110. The lower insulating layer 130 may be formed on the substrate 110 to cover the switching device, and the contact 150 may be electrically connected to the switching device.

The capacitor structure CS may include a first electrode 160, a dielectric layer 170, and a second electrode 180, which are sequentially on the contact 150. In some embodiments, the dielectric layer 170 may be between the first electrode 160 and the second electrode 180, and the first electrode 160 may be in contact with the contact 150. In some embodiments, the dielectric layer 170 may be between the first electrode 160 and the second electrode 180, and the contact 150 may be in contact with the second electrode 180.

Each of the first electrode 160 and the second electrode 180 may include a conductive material, for example, at least one of a metal and/or doped metalloid, such as doped polysilicon, ruthenium (Ru), titanium (Ti), tantalum (Ta), and tungsten (W); and/or conductive metal nitrides, such as titanium nitride (TiN), tantalum nitride (TaN), tungsten nitride (WN), chromium nitride (CrN), vanadium nitride (VN), molybdenum nitride (MoN), niobium nitride (NbN), titanium silicon nitride (TiSiN), titanium aluminum nitride (TiAlN), and tantalum aluminum nitride (TaAlN). In some embodiments, each of the first electrode 160 and the second electrode 180 may include a single layer or a multilayered structure of the materials described above.

The dielectric layer 170 may include a structure in which the plurality of first atomic layers 11 and the plurality of second atomic layers 12 of FIG. 1C are alternately stacked. The first atomic layer 11 may be in each of a lowermost layer and an uppermost layer of the stack structure included in the dielectric layer 170. For example, the first atomic layer 11 in the lowermost layer of the stack structure may face or contact the first electrode 160, and the first atomic layer 11 in the uppermost layer of the stack structure may face or contact the second electrode 180. However, the stack structure of the dielectric layer 170 is not limited thereto.

In some embodiments, the dielectric layer 170 may include substantially the same material as the multi-component thin film 1 described with reference to FIGS. 1A to 1C. The dielectric layer 170 may include at least one of a ferroelectric material layer, an anti-ferroelectric material layer, and/or a paraelectric material layer. For example, the dielectric layer 170 may include at least one of SrTiO₃, HfZrO₂, PbTiO₃, AgNbO₃, Ta₂O₃, BaTiO₃, BiFeO₃, and/or a combination thereof, without being limited thereto.

In some embodiments, the dielectric layer 170 may include an additive 170A between the first atomic layer 11 and the second atomic layer 12. In these cases, the additive 170A may be at a content ratio of less than 10% based on a total content of the dielectric layer 170. As described above, the first atomic layer 11 may include a first precursor A, and the second atomic layer 12 may include a second precursor B.

In some embodiments, the additive 170A may include a material of which a thermal decomposition temperature is lower than a thermal decomposition temperature of each of the first precursor A and the second precursor B. For example, when each of the first precursor A and the second precursor B includes a material of which a thermal decomposition temperature is 200° C., the additive 170A may include a material of which a thermal decomposition temperature is below 200° C.

In some embodiments, the dielectric layer 170 of the capacitor structure CS of the IC device 100, according to the inventive concepts, may be formed using substantially the same method as the method of manufacturing the multi-component thin film 1, which is described with reference to FIGS. 1A to 1C.

By injecting the additive 170A to the substrate 10 of which a thermal decomposition temperature is lower than the thermal decomposition temperature of the first precursor A and the thermal decomposition temperature of the second precursor B, the additive 170A may be thermally decomposed during a process of depositing the dielectric layer 170. The thermal decomposition of the additive 170A may facilitate the formation of the dielectric layer 170. In addition, crystallization of the dielectric layer 170 may improve. As a result, performance of the IC device 100 may improve.

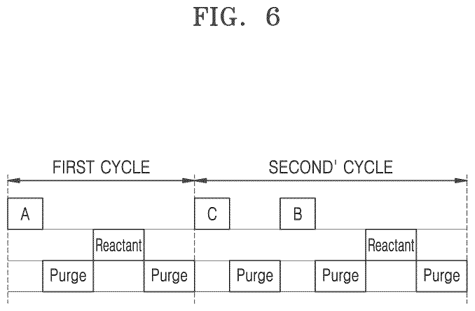

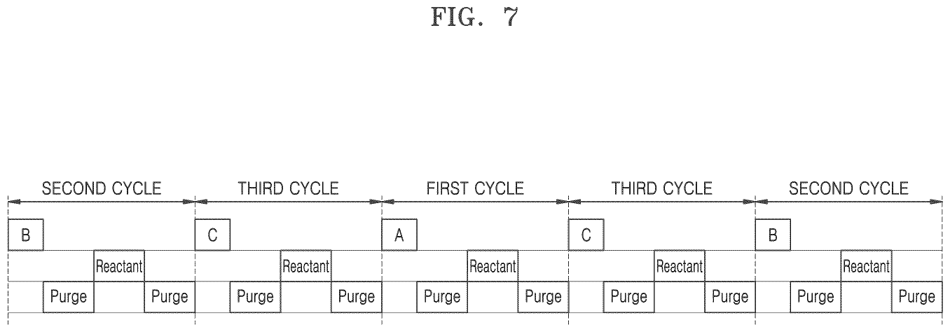

FIGS. 6 and 7 are each a diagram of a recipe for a method of manufacturing a multi-component thin film according to at least one embodiment.

Elements of the methods of manufacturing multi-component thin films, which are described below, may substantially be the same as (and/or substantially similar to) the method of manufacturing the multi-component thin film 1, which is described with reference to FIGS. 1A to 1C. Thus, for brevity, differences between the manufacturing methods shown in FIGS. 6 and 7 and the above-described method of manufacturing the multi-component thin film 1 are mainly described below and repeat descriptions thereof may be omitted. Additionally, as noted above, for brevity, the description of the multi-component thin film 1 is assumed to be for a multi-component thin film including SrTiO₃.

Referring to FIG. 6, the method of manufacturing the multi-component thin film 1 may include a first cycle and a second′ cycle.

The first cycle may refer to forming a first atomic layer on a first atomic layer 11 on a substrate 10 by supplying a first precursor A and a reactant into a process chamber including the substrate 10. The first atomic layer 11 may include, for example, TiO, without being limited thereto. Also, the first cycle may include removing a residual gas from the process chamber by supplying a purge gas before and after the operations of supplying the first precursor A and the reactant into the process chamber.

The second′ cycle may refer to an operation of supplying an additive C, a second precursor B, and a reactant into the process chamber. The second′ cycle may include removing a residual gas from the process chamber by supplying a purge gas after the additive C is supplied into the process chamber. Thereafter, the second precursor B may be directly supplied into the process chamber without supplying the reactant. Subsequently, the reactant may be supplied into the process chamber and react with the second precursor B to form a second atomic layer 12. The second atomic layer 12 may include, for example, SrO, without being limited thereto.

Also, the second′ cycle may include removing a residual gas from the process chamber by supplying a purge gas before and after the process of supplying the second precursor B into the process chamber. Thereafter, the first atomic layer 11 and the second atomic layer 12 may be crystallized by using an annealing process to form a multi-component thin film 1.

In the method of manufacturing the multi-component thin film 1, the first cycle and the second′ cycle may be performed at the same process temperature. Here, the process temperature may refer to an internal temperature of the process chamber during a process of depositing the multi-component thin film 1. In the method of manufacturing the multi-component thin film 1, according to the inventive concepts, a thermal decomposition temperature of the additive C may be lower than a thermal decomposition temperature of each of the first precursor A and the second precursor B.

In some embodiments, by repeating the first cycle and the second′ cycle, a plurality of first atomic layers 11 and a plurality of second atomic layers 12 may be alternately stacked to form the multi-component thin film 1.

Referring to FIG. 7, the method of manufacturing the multi-component thin film 1 may sequentially repeat a second cycle, a third cycle, a first cycle, the third cycle, and the second cycle.

The first to third cycles may be substantially the same as (and/or substantially similar to) the method of manufacturing the multi-component thin film 1, which is described with reference to FIGS. 1A to 1C.

Unlike in FIG. 1B, in FIG. 7, the third cycle may be performed instead of the first cycle (or the second cycle) after the second cycle (or the first cycle). That is, the method of manufacturing the multi-component thin film 1, according to the inventive concepts, may adjust the numbers of first to third cycles as needed. In these cases, the number of third cycles may be designed to be less than or equal to a sum of the number of first cycles and the number of second cycles, without being limited thereto.

In the method of manufacturing the multi-component thin film 1, according to the inventive concepts, the additive C may be injected (the third cycle) between a process of depositing the first precursor A (the first cycle) and a process of depositing the second precursor B (the second cycle). By adding the third cycle between the first cycle and the second cycle as needed, the multi-component thin film 1 may be formed.

The method of manufacturing the multi-component thin film 1 may include a process of injecting the additive C having a low thermal decomposition temperature, and thus, crystallization of the multi-component thin film 1 may improve. The additive C having a lower thermal decomposition temperature than each of the first precursor A and the second precursor B may be thermally decomposed during the third cycle. The additive C, which is thermally decomposed, may be between the first atomic layer 11 and the second atomic layer 12 and improve the crystallization of the multi-component thin film 1.

A recipe for the method of manufacturing the multi-component thin film 1, according to the inventive concepts, is not limited to the embodiments shown in FIGS. 6 and 7 and may be variously designed as needed.

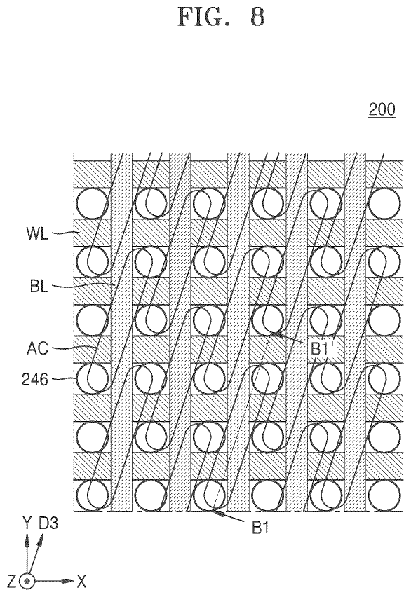

FIG. 8 illustrates the layout of an integrated circuit (IC) device according to at least one embodiment.

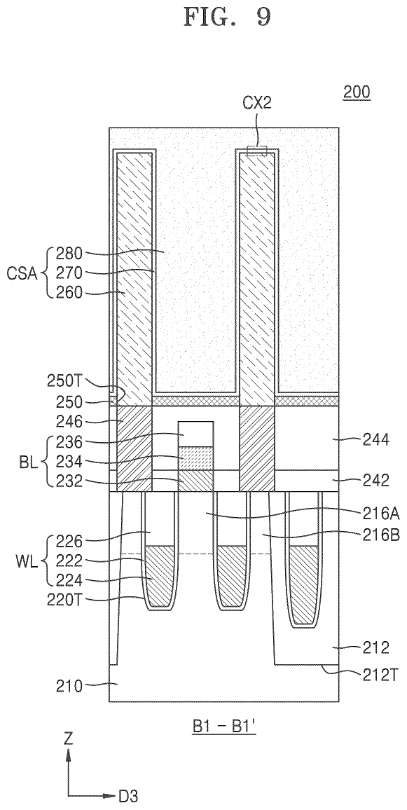

FIG. 9 is a cross-sectional view taken along line B1-B1′ of FIG. 8.

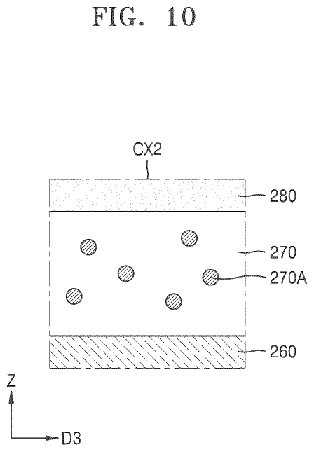

FIG. 10 is an enlarged view of portion CX2 of FIG. 9.

Referring to FIGS. 8 to 10 together, an IC device 200 may include a capacitor structure CSA formed on a buried channel array transistor (BCAT) structure.

A substrate 210 may include active regions AC defined by a device isolation film 212. In some embodiments, the substrate 210 may include a silicon (Si) wafer.

In some embodiments, the device isolation film 212 may have a shallow trench isolation (STI) structure. For example, the device isolation film 212 may include an insulating material filling a device isolation trench 212T formed in the substrate 210. The insulating material may include fluoride silicate glass (FSG), undoped silicate glass (USG), boro-phospho-silicate glass (BPSG), phospho-silicate glass (PSG), flowable oxide (FOX), plasma-enhanced tetra-ethyl-ortho-silicate (PE-TEOS), or tonen silazane (TOSZ), without being limited thereto.

Each of the active regions AC may have a relatively long island shape with a minor axis and a major axis. As shown in FIG. 8, the major axis of the active region AC may be arranged in a direction D3 that is parallel to a top surface of the substrate 210. In some embodiments, the active region AC may have a first conductivity type. The first conductivity type may be p type (or n type).

The substrate 210 may include a word line trench 220T extending in an X direction. The word line trench 220T may intersect with the active region AC and be formed to have a predetermined depth from the top surface of the substrate 210. A portion of the word line trench 220T may extend into the device isolation film 212, and a portion of the word line trench 220T formed in the device isolation film 212 may include a bottom surface at a lower level than a portion of the word line trench 220T formed in the active region AC.

A first source/drain region 216A and a second source/drain region 216B may be on both sides of the word line trench 220T in an upper portion of the active region AC. Each of the first source/drain region 216A and the second source/drain region 216B may be a doped region of a second conductivity type that is different from the first conductivity type. The second conductivity type may be n type (or p type).

A word line WL may be formed inside the word line trench 220T. The word line WL may include a gate insulating layer 222, a gate electrode 224, and a gate capping layer 226, which are sequentially formed on an inner wall of the word line trench 220T.

The gate insulating layer 222 may be conformally formed on the inner wall of the word line trench 220T to a predetermined thickness. The gate insulating layer 222 may include an insulator, such as at least of silicon oxide, silicon nitride, silicon oxynitride, oxide/nitride/oxide (ONO), and a high-k dielectric material having a higher dielectric constant than silicon oxide. For example, the gate insulating layer 222 may have a dielectric constant of about 10 to about 25. In some embodiments, the gate insulating layer 222 may include HfO₂, Al₂O₃, HfAlO₃, Ta₂O₃, TiO₂, or a combination thereof, without being limited thereto.

The gate electrode 224 may be formed to a predetermined height from a bottom portion of the word line trench 220T on the gate insulating layer 222 to fill the word line trench 220T. The gate electrode 224 may include a work-function control layer (not shown) on the gate insulating layer 222 and a buried metal layer (not shown) filling the bottom portion of the word line trench 220T on the work-function control layer. For example, the work-function control layer may include a metal, a metal nitride, or a metal carbide, such as titanium (Ti), titanium nitride (TiN), titanium aluminum nitride (TiAlN), titanium aluminum carbide (TiAlC), titanium aluminum carbonitride (TiAlCN), titanium silicon carbonitride (TiSiCN), tantalum (Ta), tantalum nitride (TaN), tantalum aluminum nitride (TaAlN), tantalum aluminum carbonitride (TaAlCN), and tantalum silicon carbonitride (TaSiCN), and the buried metal layer may include at least one of W, WN, TiN, and TaN.

The gate capping layer 226 may fill a remaining portion of the word line trench 220T on the gate electrode 224. For example, the gate capping layer 226 may include an insulator, such as at least one of silicon oxide, silicon oxynitride, and silicon nitride.

A bit line BL extending in a Y direction that is perpendicular to the X direction may be formed on the first source/drain region 216A. The bit line BL may include a bit line contact 232, a bit line conductive layer 234, and a bit line capping layer 236, which are sequentially stacked on the substrate 210. For example, the bit line contact 232 may include polysilicon, and the bit line conductive layer 234 may include a metal material. The bit line capping layer 236 may include an insulating material, such as silicon nitride or silicon oxynitride. Although a bottom surface of the bit line contact 232 is illustrated as being at the same level as a top surface of the substrate 210, in another case, the bottom surface of the bit line contact 232 may be formed at a lower level than the top surface of the substrate 210.

In at least some embodiments, a bit line middle layer (not shown) may be between the bit line contact 232 and the bit line conductive layer 234. The bit line middle layer may include a metal silicide (e.g., tungsten silicide) or a metal nitride (e.g., tungsten nitride). A bit line spacer (not shown) may be further formed on a sidewall of the bit line BL. The bit line spacer may include a single layer or a multilayered structure, which includes an insulating material, such as silicon oxide, silicon oxynitride, or silicon nitride. Also, the bit line spacer may further include an air space (not shown).

A first interlayer insulating film 242 may be formed on the substrate 210, and the bit line contact 232 may pass through the first interlayer insulating film 242 and be connected to the first source/drain region 216A. The bit line conductive layer 234 and the bit line capping layer 236 may be on the first interlayer insulating film 242. A second interlayer insulating film 244 may be on the first interlayer insulating film 242 to cover a side surface and a top surface of each of the bit line conductive layer 234 and the bit line capping layer 236.

A contact structure 246 may be on the second source/drain region 216B. A sidewall of the contact structure 246 may be surrounded by the first and second interlayer insulating films 242 and 244. In some embodiments, the contact structure 246 may include a lower contact pattern (not shown), a metal silicide layer (not shown), and an upper contact pattern (not shown), which are sequentially stacked on the substrate 210, and a barrier layer (not shown) surrounding a side surface and a bottom surface of the upper contact pattern. In some embodiments, the lower contact pattern may include polysilicon, and the upper contact pattern may include a metal material. The barrier layer may include a metal nitride with conductivity.

Capacitor structures CSA may be formed on the second interlayer insulating film 244. Each of the capacitor structures CSA may include a lower electrode 260 electrically connected to the contact structure 246, a dielectric layer 270 on the lower electrode 260, and an upper electrode 280 on the dielectric layer 270. Moreover, an etch stop film 250 including an opening 250T may be formed on the second interlayer insulating film 244, and a bottom portion of the lower electrode 260 may be inside the opening 250T of the etch stop film 250.

The capacitor structures CSA are illustrated as being repeatedly arranged in the X direction and the Y direction on the contact structures 246 that are repeatedly arranged in the X direction and the Y direction. However, in at least some embodiments (unlike the one shown), the capacitor structures CSA may be arranged in a hexagonal shape (e.g., a honeycomb structure) on the contact structures 246 that are repeatedly arranged in the X direction and the Y direction. In these cases, a landing pad (not shown) may be formed between the contact structure 246 and the capacitor structure CSA.

The lower electrode 260 may be formed in a pillar shape extending in a Z direction on the contact structure 246, and the dielectric layer 270 may be conformally formed on a top surface and a sidewall of the lower electrode 260. The upper electrode 280 may be on the dielectric layer 270.

The lower electrode 260, the dielectric layer 270, and the upper electrode 280 may substantially and respectively be the same as and/or similar to the first electrode 160, the dielectric layer 170, and the second electrode 180, which are described with reference to FIGS. 4 and 5. In addition, the dielectric layer 270 of the capacitor structure CSA of the IC device 200 according to the inventive concepts may be formed by using substantially the same method as the method of manufacturing the multi-component thin film 1, which is described with reference to FIGS. 1A to 1C. Thus, a detailed description of a method of forming the dielectric layer 270 is omitted.

By injecting an additive 270A of which a thermal decomposition temperature is lower than each of a thermal decomposition temperature of the first precursor A and a thermal decomposition temperature of a second precursor B, the additive 270A may be thermally decomposed during a process of depositing the dielectric layer 270. The thermal decomposition of the additive 270A may facilitate the formation of the dielectric layer 270. In addition, crystallization of the dielectric layer 270 may improve. As a result, performance of the IC device 200 may improve.

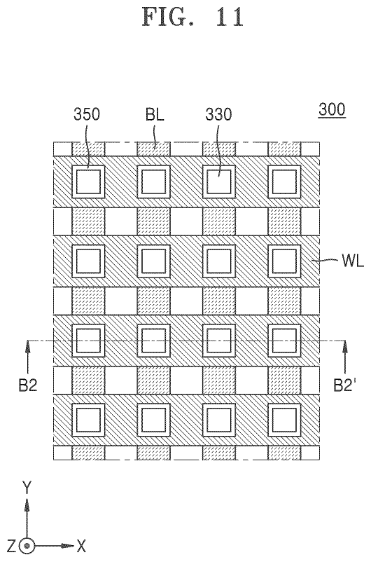

FIG. 11 illustrates the layout of an IC device according to at least one embodiment.

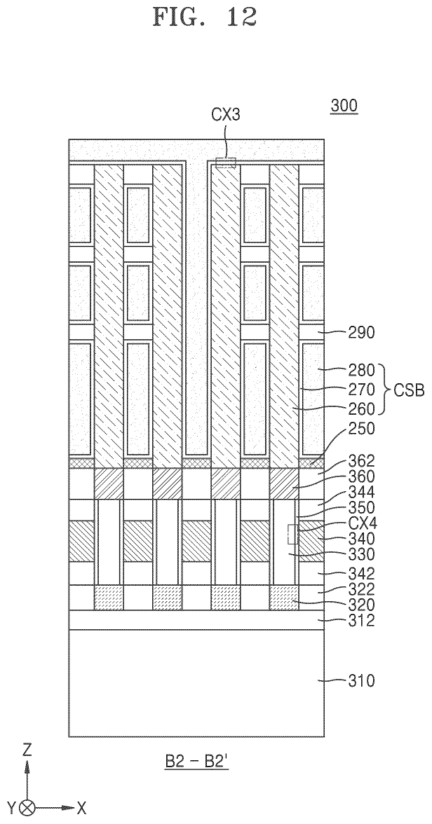

FIG. 12 is a cross-sectional view taken along line B2-B2′ of FIG. 11.

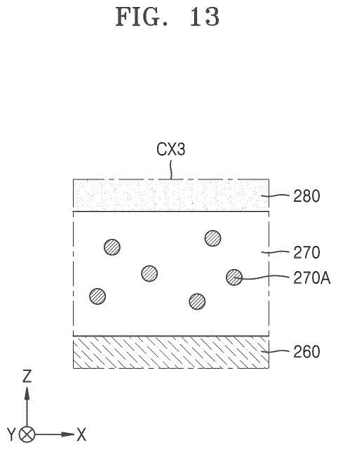

FIG. 13 is an enlarged view of portion CX3 of FIG. 12.

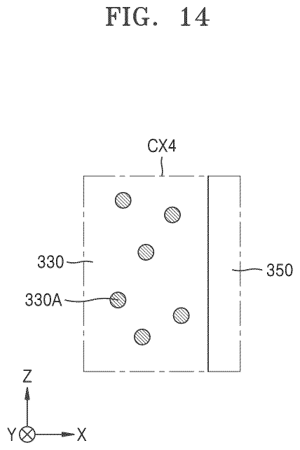

FIG. 14 is an enlarged view of portion CX4 of FIG. 12.

Referring to FIGS. 11 to 14, an IC device 300 may include a capacitor structure CSB on a vertical channel transistor (VCT) structure.

A lower insulating layer 312 may be on a substrate 310. On the lower insulating layer 312, a plurality of first conductive patterns 320 may be apart from each other in an X direction and extend in a Y direction. A plurality of first insulating patterns 322 may be on the lower insulating layer 312 to fill spaces between the plurality of first conductive patterns 320. Each of the plurality of first conductive patterns 320 may correspond to a bit line BL of the IC device 300.

In some embodiments, the plurality of first conductive patterns 320 may include a conductive material, such as doped polysilicon, a metal, a conductive metal nitride, a conductive metal silicide, a conductive metal oxide, and/or a combination thereof. For example, the plurality of first conductive patterns 320 may include doped polysilicon, aluminum (Al), copper (Cu), titanium (Ti), tantalum (Ta), ruthenium (Ru), tungsten (W), molybdenum (Mo), platinum (Pt), nickel (Ni), cobalt (Co), titanium nitride (TiN), tantalum nitride (TaN), tungsten nitride (WN), niobium nitride (NbN), titanium aluminide (TiAl), titanium aluminum nitride (TiAlN), titanium silicide (TiSi), titanium silicon nitride (TiSiN), tantalum silicide (TaSi), tantalum silicon nitride (TaSiN), ruthenium titanium nitride (RuTiN), nickel silicide (NiSi), cobalt silicide (CoSi), iridium oxide (IrO), ruthenium oxide (RuO), or a combination thereof, without being limited thereto. Each of the plurality of first conductive patterns 320 may include a single layer or a multilayered structure of the materials described above. In some embodiments, the plurality of first conductive patterns 320 may include a two-dimensional (2D) semiconductor material. For example, the 2D semiconductor material may include graphene, carbon nanotubes, or a combination thereof.

A channel layer 330 may be arranged in the form of islands apart from each other in the X direction and the Y direction on the plurality of first conductive patterns 320. The channel layer 330 may have a channel width in the X direction and a channel height in a Z direction, and the channel height may be greater than the channel width. A bottom portion of the channel layer 330 may function as a first source/drain region (not shown), an upper portion of the channel layer 330 may function as a second source/drain region (not shown), and a portion of the channel layer 330 between the first and second source/drain regions may function as a channel region (not shown). A VCT may refer to a structure in which a channel length of the channel layer 330 extends from the substrate 310 in the Z direction.

In some embodiments, the channel layer 330 may include an oxide semiconductor, for example, InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, and/or a combination thereof, wherein the subscripts x, y, and z represent real numbers. The channel layer 330 may include a single layer or a multilayered structure of the oxide semiconductor described above.

In some embodiments, the channel layer 330 may be formed using substantially the same (and/or similar) method as the method of manufacturing the multi-component thin film 1, which is described with reference to FIGS. 1A to 1C. Thus, a detailed description of a method of forming the channel layer 330 is omitted.

By injecting an additive 330A of which a thermal decomposition temperature is lower than each of a thermal decomposition temperature of a first precursor and a thermal decomposition temperature of a second precursor, the additive 330A may be thermally decomposed during a process of depositing the channel layer 330. The thermal decomposition of the additive 330A may facilitate the formation of the channel layer 330. In addition, crystallization of the channel layer 330 may improve. As a result, the performance of the IC device 300 may improve.

In some embodiments, a gate electrode 340 may surround a sidewall of the channel layer 330 and extend in the X direction. In FIG. 12, the gate electrode 340 may be a gate-all-around type gate electrode entirely surrounding the sidewall of the channel layer 330. The gate electrode 340 may correspond to the word line WL of the IC device 300.

In other embodiments, the gate electrode 340 may be a dual-gate-type gate electrode. For example, the gate electrode 340 may include a first sub-gate electrode (not shown) facing a first sidewall of the channel layer 330 and a second sub-gate electrode (not shown) facing a second sidewall opposite to the first sidewall of the channel layer 330.

In still other embodiments, the gate electrode 340 may be a single-gate-type gate electrode, which covers only the first sidewall of the channel layer 330 and extends in the X direction.

The gate electrode 340 may include doped polysilicon, a metal, a conductive metal nitride, a conductive metal silicide, a conductive metal oxide, or a combination thereof. For example, the gate electrode 340 may include a conductive material, such as doped polysilicon, Al, Cu, Ti, Ta, Ru, W, Mo, Pt, Ni, Co, TiN, TaN, WN, NON, TiAl, TiAlN, TiSi, TiSiN, TaSi, TaSiN, RuTiN, NiSi, CoSi, IrOx, RuOx, or a combination thereof, without being limited thereto.

A gate insulating layer 350 may surround the sidewall of the channel layer 330 and be between the channel layer 330 and the gate electrode 340. In some embodiments, the gate insulating layer 350 may include a silicon oxide film, a silicon oxynitride film, a high-k dielectric film having a higher dielectric constant than the silicon oxide film, or a combination thereof. The high-k dielectric film may include a metal oxide or a metal oxynitride. For example, the high-k dielectric film included in the gate insulating layer 350 may include HfO₂, HfSiO, HfSiON, HfTaO, HfTIO, HfZrO, ZrO₂, Al₂O₃, or a combination thereof, without being limited thereto.

A first buried insulating layer 342 surrounding a lower sidewall of the channel layer 330 may be on the plurality of first insulating patterns 322. A second buried insulating layer 344 surrounding the lower sidewall of the channel layer 330 and covering the gate electrode 340 may be on the first buried insulating layer 342.

Capacitor contacts 360 may be on the channel layer 330. The capacitor contacts 360 may vertically overlap the channel layer 330 and be arranged in a matrix form apart from each other in the X direction and the Y direction. The capacitor contact 360 may include a conductive material, such as doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrO, RuO, or a combination thereof, without being limited thereto. An upper insulating layer 362 may surround a sidewall of the capacitor contact 360 on the second buried insulating layer 344.

An etch stop film 250 may be on the upper insulating layer 362, and a capacitor structure CSB may be on the etch stop film 250. The capacitor structure CSB may include a lower electrode 260, a dielectric layer 270, and an upper electrode 280. The lower electrode 260 may be electrically connected to the capacitor contact 360, the dielectric layer 270 may cover the lower electrode 260, and the upper electrode 280 may cover the lower electrode 260 on the dielectric layer 270. A support member 290 may be on a sidewall of the lower electrode 260. The support member 290 may include an insulator material.

The lower electrode 260, the dielectric layer 270, and the upper electrode 280 may substantially and respectively be the same as the first electrode 160, the dielectric layer 170, and the second electrode 180, which are described with reference to FIGS. 2 and 3. In addition, the dielectric layer 270 of the capacitor structure CSB of the IC device 300 according to the inventive concepts may be formed by using substantially the same method as the method of manufacturing the multi-component thin film 1, which is described with reference to FIGS. 1A to 1C. Thus, a detailed description of a method of forming the dielectric layer 270 is omitted.

In conclusion, by injecting an additive 270A of which a thermal decomposition temperature is lower than each of a thermal decomposition temperature of the first precursor A and a thermal decomposition temperature of a second precursor B, the additive 270A may be thermally decomposed during a process of depositing the dielectric layer 270. The thermal decomposition of the additive 270A may facilitate the formation of the dielectric layer 270. In addition, crystallization of the dielectric layer 270 may improve. As a result, performance of the IC device 300 may improve.

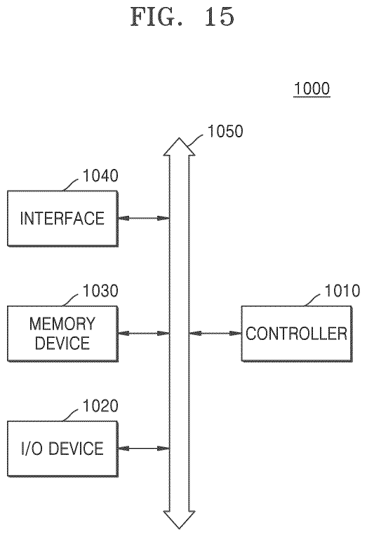

FIG. 15 is a view showing the configuration of a system 1000 including an IC device, according to at least one embodiment.

Referring to FIG. 15, the system 1000 may include a controller 1010, an input/output (I/O) device 1020, a memory device 1030, an interface 1040, and a bus 1050.

The system 1000 may be a mobile system or a system configured to transmit and receive information. In some embodiments, the mobile system may be a portable computer, a web tablet, a mobile phone, a digital music player, or a memory card.

The controller 1010 may be configured to control an execution program in the system 1000. The controller 1010 may include a microprocessor, a digital signal processor, a microcontroller, or a device similar thereto.

The I/O device 1020 may be used to input or output data of the system 1000. The system 1000 may be connected to an external device (e.g., a personal computer or a network) by using the I/O device 1020 and exchange data with the external device. The I/O device 1020 may include, for example, a touch screen, a touch pad, a keyboard, or a display.

The memory device 1030 may store data for an operation of the controller 1010 or data processed by the controller 1010. The memory device 1030 may include any one of the IC devices 100, 200, and 300 according to the embodiments described above.

The interface 1040 may be a data transmission path between the system 1000 and an external device. The controller 1010, the I/O device 1020, the memory device 1030, and the interface 1040 may communicate with each other through the bus 1050.

While the inventive concepts have been particularly shown and described with reference to embodiments thereof, it will be understood that various changes in form and details may be made therein without departing from the spirit and scope of the following claims.

What is claimed is:

1. A method of manufacturing a multi-component thin film, the method comprising:
loading a substrate into a process chamber;
performing a first cycle, the first cycle comprising forming a first atomic layer on the substrate using an atomic layer deposition process to deposit a first precursor;
performing a third cycle, the third cycle comprising injecting an additive onto the first atomic layer; and
performing a second cycle, the second cycle comprising forming a second atomic layer on the first atomic layer and the additive using an atomic layer deposition process to deposit a second precursor,
wherein a thermal decomposition temperature of the additive is lower than a thermal decomposition temperature of the first precursor and lower than a thermal decomposition temperature of the second precursor.

2. The method of claim 1, wherein a process temperature of the method of manufacturing the multi-component thin film is lower than the thermal decomposition temperature of the first precursor, lower than the thermal decomposition temperature of the second precursor, and higher than the thermal decomposition temperature of the additive.

3. The method of claim 2, wherein, at the process temperature, a growth per cycle (GPC) of the additive is more than 3 times a GPC of the first precursor and more than 3 times a GPC of the second precursor.

4. The method of claim 1, wherein
each of the first precursor and the second precursor comprises a cyclopentadienyl ligand, and
the additive comprises an amine ligand.

5. The method of claim 1, further comprising:
repeating the performing of the first, third, and second cycles,
wherein a number of times the third cycle is performed is less than or equal to a sum of a number of times the first cycle is performed and a number of times the second cycle is performed.

6. The method of claim 1, wherein
the first cycle comprises supplying the first precursor into the process chamber, oxidizing the first precursor by supplying an oxidant into the process chamber, and purging a residual gas from the process chamber, and
the second cycle comprises supplying the second precursor into the process chamber, oxidizing the second precursor by supplying an oxidant into the process chamber, and purging a residual gas from the process chamber.

7. The method of claim 1, wherein the third cycle comprises supplying the additive into the process chamber, supplying an oxidant into the process chamber, and purging a residual gas from the process chamber.

8. The method of claim 1, wherein the manufacturing of the multi-component thin film includes manufacturing the multi-component thin film such that the multi-component thin film comprises a perovskite material.

9. The method of claim 1, wherein the manufacturing of the multi-component thin film includes manufacturing the multi-component thin film such that the multi-component thin film comprises an oxide semiconductor.

10. The method of claim 1, wherein the performing the third cycle includes injecting the additive such that the additive is at a content ratio of 10% or less based on a total content of the multi-component thin film.

11. A multi-component thin film comprising:
a plurality of atomic layers comprising a least a first atomic layer and a second atomic layer with different precursors from each other; and
an additive between two adjacent ones of the plurality of atomic layers,
wherein the additive comprises a material with a thermal decomposition temperature lower than thermal decomposition temperatures of both the different precursors.

12. The multi-component thin film of claim 11, wherein the additive is at a content ratio of 10% or less based on a total content of the multi-component thin film.

13. The multi-component thin film of claim 11, wherein
the precursor comprises a cyclopentadienyl ligand, and
the additive comprises an amine ligand.

14. The multi-component thin film of claim 11, wherein the multi-component thin film comprises at least one of a perovskite material or an oxide semiconductor.

15. The multi-component thin film of claim 11, wherein the multi-component thin film includes
an alternating stack of the first and second atomic layers, and
the additive between two adjacent ones of the first and second atomic layers.

16. An integrated circuit device comprising:
a transistor on a substrate; and
a capacitor structure electrically connected to the transistor,
wherein the capacitor structure comprises
a first electrode;
a second electrode, and
a dielectric layer between the first and second electrodes,
wherein the dielectric layer comprises a plurality of atomic layers and an additive between two adjacent ones of the plurality of atomic layers, wherein the plurality of atomic layers comprise at least a first atomic layer and a second atomic layer with different precursors from each other, and
the additive comprises a material with a thermal decomposition temperature lower than thermal decomposition temperatures of both the different precursors.

17. The integrated circuit device of claim 16, wherein the additive is at a content ratio of 10% or less based on a total content of the dielectric layer.

18. The integrated circuit device of claim 16, wherein
the precursor comprises a cyclopentadienyl ligand, and
the additive comprises an amine ligand.

19. The integrated circuit device of claim 16, wherein the dielectric layer comprises at least one of a perovskite material or an oxide semiconductor.

20. The integrated circuit device of claim 16, wherein the dielectric layer includes
an alternating stack of the first and second atomic layers, and
the additive between two adjacent ones of the first and second of atomic layers.
